(19) United States
(12) Patent Application Publication
(10) Pub. No.: US 2008/0238561 A1
(43) Pub. Date: Oct. 2, 2008

(54) PIEZOELECTRIC OSCILLATOR

(76) Inventors: Takashi Otsuka, Kanagawa (JP); Hisato Takeuchi, Kanagawa (JP)

Correspondence Address: MCDERMOTT WILL & EMERY LLP, 600 13TH STREET, NW, WASHINGTON, DC, 20005-3096, US

(21) Appl. No.: 12/058,231

(22) Filed: Mar. 28, 2008

(30) Foreign Application Priority Data
Mar. 30, 2007 (JP) P. 2007-094573

(51) Int. Cl. H03B 5/32; H03B 5/36

(52) U.S. Cl. 331/158; 331/116 FE

(57) ABSTRACT

For a piezoelectric oscillator according to the present invention, an oscillator circuit includes: a piezoelectric vibrator; an NMOS transistor and a PMOS transistor that constitute an amplifier connected in parallel to the piezoelectric vibrator; and load capacitors connected in parallel to the piezoelectric vibrator. The gate terminals of the NMOS transistor and the PMOS transistor, which are constituents of the amplifier, are connected by a DC cut capacitor, and the gate terminal of the NMOS transistor and the output terminal of the amplifier are connected by a feedback resistor. An arbitrary bias voltage, to be applied to the gate terminal of the PMOS transistor via a high-frequency elimination resistor, is generated by a circuit provided by a diode-connected, second PMOS transistor.

### BACKGROUND OF THE INVENTION

1. Field of the Invention

The present invention relates to a piezoelectric oscillator for oscillating a piezoelectric vibrator, such as a crystal vibrator.

2. Description of the Related Art

A temperature-compensated crystal oscillator is a crystal oscillator that is employed to provide a reference frequency for a cellular phone, and that offsets a thermal characteristic of a crystal vibrator (a piezoelectric vibrator), and possesses a property such that there is little variation in frequency due to temperature changes. Regards oscillator use, there has been a recent increased demand for temperature-compensated crystal oscillators that can be operated, at low voltages, in cellular phones and GPS systems.

A conventional crystal oscillator circuit (prior art 1) is shown in FIG. 9. This crystal oscillator circuit, employed for a temperature-compensated crystal oscillator, comprises a CMOS inverter amplifier 40, which includes a PMOS transistor 2 and an NMOS transistor 3. Further, for the crystal oscillation circuit in FIG. 9, an oscillation loop is formed using the CMOS inverter amplifier 40, a limit resistor 4, load capacitors 6 and 7 and a feedback resistor 1, and a negative resistance is provided between terminals that connect a crystal vibrator 5 (see, for example, patent document 1).

Another crystal oscillator circuit (prior art 2) is shown in FIG. 10. The crystal oscillator circuit in FIG. 10 comprises an NMOS transistor 10 and a constant current source 8. For this crystal oscillator circuit, an oscillation loop is formed using an NMOS transistor 10, a limit resistor 11, load capacitors 13 and 14 and a feedback resistor 9, and a negative resistance is provided between terminals that connect a crystal vibrator 12.

Patent Document 1: JP-A-2003-318417

In the crystal oscillator circuit in FIG. 9 for prior art 1, when the operating power voltage of the temperature-compensated crystal oscillator is dropped, the internal regulator voltage for driving the CMOS inverter amplifier 40, provided for the crystal oscillator circuit, is also reduced. Therefore, in order to provide a temperature-compensated oscillator that can be operated at a low voltage, the crystal oscillator must employ the CMOS inverter amplifier 40 to perform a low-voltage operation.

In order to obtain an appropriate negative resistance for the crystal oscillator circuit in prior art 1, generally, about three times the threshold voltage of an MOS transistor is required as the internal regulator voltage that drives the CMOS inverter amplifier 40.

When the internal regulator voltage is dropped, a satisfactory gate-source voltage VGS cannot be obtained, and the gain of the CMOS inverter amplifier 40 is lowered. As a result, problems such as degradation of the negative resistance and a delayed oscillation start time occur.

As one method for improving the negative resistance, the size of an MOS transistor is increased to obtain a large gain for the CMOS inverter amplifier 40. When this method is employed, however, the consumption of power is increased.

Further, for the crystal oscillator in FIG. 10 for the prior art 2, in order to obtain a negative resistance, the current that is supplied to the NMOS transistor 10 must be increased.

### SUMMARY OF THE INVENTION

The present invention is provided while taking these conventional problems into account, and one objective of the present invention is to provide a piezoelectric oscillator that can be operated at a low voltage.

A piezoelectric oscillator according to the invention comprises an amplifier connected in parallel to a piezoelectric vibrator; and a load capacitor connected in parallel to the piezoelectric vibrator, wherein the amplifier includes an inverter that is comprised of a first PMOS transistor and an NMOS transistor that are connected in series, a DC cut capacitor connected between a gate terminal of the first PMOS transistor and a gate terminal of the NMOS transistor and a feedback resistor connected to the gate terminal of the NMOS transistor and an output terminal of the amplifier, and wherein a bias voltage that is smaller than half of a source voltage of the inverter is applied to the gate terminal of the first PMOS transistor.

According to this arrangement, when a bias voltage that is smaller than half of a source voltage of the inverter is applied to the gate terminal of the first PMOS transistor, which is a constituent of the amplifier, the gate-source voltage VGS of the first PMOS transistor can be raised, and accordingly, a gain of the amplifier can be increased. Therefore, during a low-voltage operation, a satisfactory negative resistance can still be obtained. Furthermore, since the phases of the oscillation amplitudes of the gate terminal of the first PMOS transistor and of the gate terminal of the NMOS transistor are the same, when the NMOS transistor is ON, the PMOS transistor is OFF. Thus, the consumption of power can be reduced, compared with when a constant current is supplied to the NMOS transistor.

The piezoelectric oscillator of this invention further comprises a high-frequency elimination resistor connected to the gate terminal of the first PMOS transistor, wherein the predetermined bias voltage is to be applied via the high-frequency elimination resistor.

Furthermore, the piezoelectric oscillator of this invention comprises a bias voltage generator circuit for generating the predetermined bias voltage, wherein the bias voltage generator circuit includes a second PMOS transistor that is diode-connected, and a current source connected in series to the second PMOS transistor. In addition, the piezoelectric oscillator of this invention comprises a bias voltage generator circuit for generating the predetermined bias voltage, wherein the bias voltage generator circuit includes a second PMOS transistor that is diode-connected, and a load resistor connected in series to the second PMOS transistor.

According to this arrangement, the bias voltage generator circuit generates a bias voltage that offsets a variation in the threshold voltage of the first PMOS transistor and the thermal characteristic thereof, and applies the bias voltage to the gate terminal of the first PMOS transistor. Thus, power consumption, variations in the negative resistance and changes due to the thermal characteristics can be reduced. Further, since with this arrangement, noise produced by the power source of the amplifier can be offset, while phase noise can also be reduced.

Moreover, according to the present invention, a piezoelectric oscillator comprises an amplifier connected in parallel to a piezoelectric vibrator; and a load capacitor connected in parallel to the piezoelectric vibrator, wherein the amplifier includes an inverter that is comprised of a PMOS transistor and an NPN transistor connected in series, a DC cut capacitor connected between a gate terminal of the PMOS transistor and a base terminal of the NPN transistor, and a feedback resistor connected to a gate terminal of the NPN transistor and an output terminal of the amplifier, and wherein a bias voltage that is smaller than half of a source voltage of the inverter is to be applied to the gate terminal of the PMOS transistor.

According to this arrangement, since an arbitrary bias voltage is applied to the gate of the PMOS transistor that is a constituent of the amplifier, the gate-source voltage of the PMOS transistor can be raised, and accordingly, the amplifier gain can be increased. Further, by using the NPN transistor, a greater improvement in the negative resistance can be obtained, even during a low-voltage operation.

According to the piezoelectric oscillator of the invention, a predetermined bias voltage is applied to the gate terminal of the first PMOS transistor, which is a constituent of the amplifier, the gate-source voltage VGS of the first PMOS transistor can be raised and the gain of the amplifier can be increased. Therefore, a satisfactory negative resistance can still be obtained during a low-voltage operation.

### BRIEF DESCRIPTION OF THE DRAWINGS

FIG. 1 is a schematic circuit diagram showing the arrangement of a piezoelectric oscillator according to a first embodiment of the present invention.

FIG. 2 is a schematic circuit diagram showing the arrangement of a piezoelectric oscillator according to a second embodiment of the present invention.

FIG. 3 is a diagram showing waveforms at terminals for prior art 1.

FIG. 4 is a diagram showing waveforms at terminals for the first embodiment of the invention.

FIG. 5 is a schematic circuit diagram showing the arrangement of a piezoelectric oscillator according to a third embodiment of the present invention.

FIG. 6 is a schematic circuit diagram showing the arrangement of a piezoelectric oscillator according to a fourth embodiment of the present invention.

FIG. 7 is a schematic circuit diagram showing the arrangement of a piezoelectric oscillator according to a fifth embodiment of the present invention.

FIG. 8 is a schematic circuit diagram showing another arrangement of a piezoelectric oscillator according to a sixth embodiment of the present invention.

FIG. 9 is a schematic circuit diagram showing the arrangement of a first conventional piezoelectric oscillator.

FIG. 10 is a schematic circuit diagram showing the arrangement of a second conventional piezoelectric oscillator.

### DESCRIPTION OF THE PREFERRED EMBODIMENTS

The embodiments of the present invention will now be described while referring to drawings.

### First Embodiment

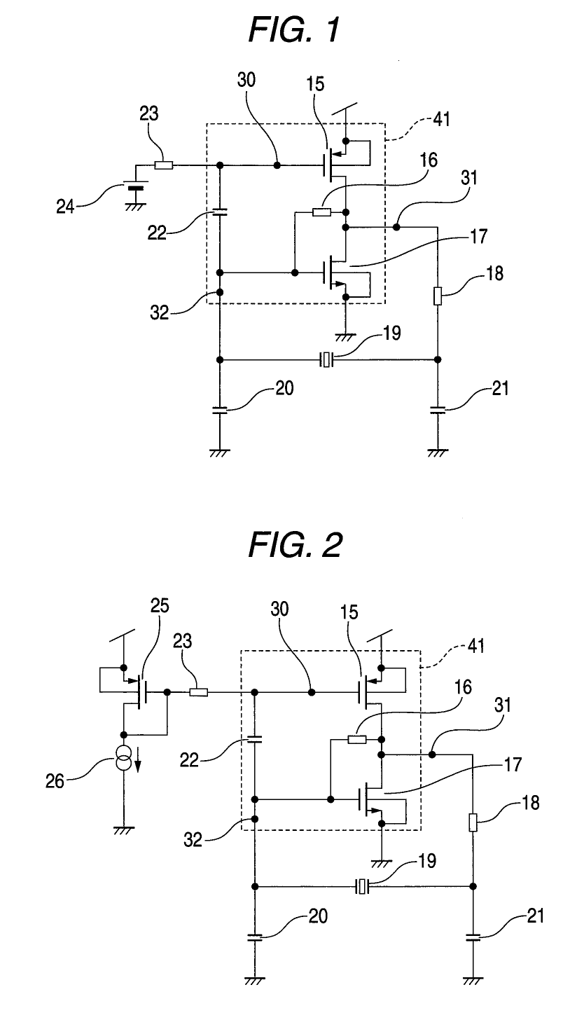

FIG. 1 is a schematic diagram showing the arrangement of a piezoelectric oscillator according to a first embodiment of the present invention. The piezoelectric oscillator of the first embodiment of the invention comprises an oscillator circuit that includes: a piezoelectric vibrator 19, such as a crystal vibrator; an NMOS transistor 17 and a PMOS transistor 15 that constitute an amplifier 41 connected in parallel to the piezoelectric vibrator 19; and load capacitors 20 and 21 that are connected in parallel to the piezoelectric vibrator 19. A gate terminal 32 of the NMOS transistor 17 and a gate terminal 30 of the PMOS transistor 15, both of which are constituents of the CMOS inverter amplifier 41, are connected by a DC cut capacitor 22, and the gate terminal 32 of the NMOS transistor 17 and an output terminal 31 of the CMOS inverter amplifier 41 are connected by a feedback resistor 16. Further, an arbitrary bias voltage 24 is to be applied to the gate terminal 30 of the PMOS transistor 15 via a high-frequency elimination resistor 23.

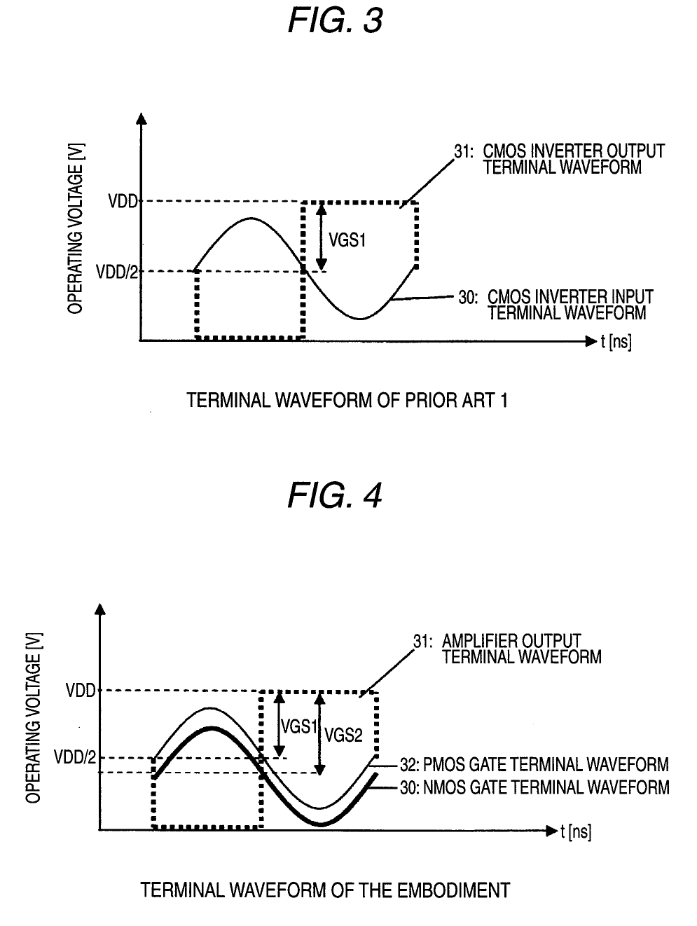

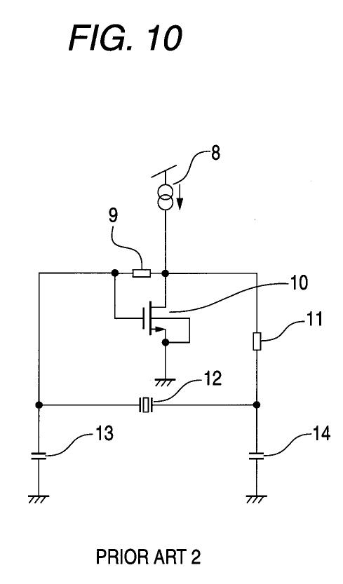

The operation of the piezoelectric oscillator of this embodiment will now be described while referring to FIGS. 3 and 4. FIG. 3 is a graph showing waveforms at the terminals of the oscillator circuit in FIG. 10 for prior art 1. The gate terminals of the PMOS transistor 2 and the NMOS transistor 3, which constitute the CMOS inverter amplifier 40, are short-circuited, and an output waveform 31 of the CMOS inverter amplifier 40 (a signal waveform at the terminal 31 in FIG. 6) is propagated with a 180° phase delay relative to an input waveform 30 (a signal waveform at the terminal 30 in FIG. 6).

Furthermore, the input terminal 30 and the output terminal 31 of the CMOS inverter amplifier 40 are connected via the feedback resistor 1, and their bias voltages are equal. For example, when the power voltage VDD of the CMOS inverter amplifier 40 is 1.5 V, the gate voltage (a voltage at the gate terminals of the PMOS transistor 2 and the NMOS transistor 3) is an intermediate voltage, i.e., 0.75 V, and the gate-source voltage VGS1 of an MOS transistor, which is a constituent of the CMOS inverter amplifier 40, is also 0.75 V. Since the threshold voltage of the general MOS transistor is about 0.7 V, a satisfactory gain cannot be obtained for the CMOS inverter amplifier 40.

FIG. 4 is a graph showing waveforms at the terminals of the piezoelectric oscillator for the first embodiment of the invention. In the piezoelectric oscillator shown in FIG. 1, the DC cut capacitor 22 is arranged between the NMOS transistor 17 for the gate terminal 30 of the PMOS transistor 15 and the gate terminal 32 of the NMOS transistor 17, and an arbitrary bias voltage 24 is applied to the gate terminal 30 of the PMOS transistor 15. The bias voltage is generated, for example, through resistance-division of an internal regulator voltage VDD.

According to the piezoelectric oscillator shown in FIG. 1, the same phase is obtained for a signal at the gate terminal 30 of the PMOS transistor 15 and a signal at the gate terminal 32 of the NMOS transistor 17, as shown in FIG. 4.

When as shown in FIG. 4 the gate-source voltage of the PMOS transistor 15 is raised to VGS2 from VGS1 used for prior art 1, a satisfactorily large gain can be obtained for the PMOS transistor 15, and a gain for the amplifier 41 can be increased. Here, as shown in FIG. 4, in order to raise the gate-source voltage of the PMOS transistor 15 from VGS1 to VGS2, the arbitrary bias voltage 24 that is smaller than half of the power voltage VDD of the amplifier 41 needs to be applied to the gate terminal of the PMOS transistor 15. In particular, when the power voltage VDD is 1.5 V, the bias voltage that is smaller than 0.75 V that is an intermediate voltage needs to be applied to the gate terminal of the PMOS transistor 15.

As described above, according to the piezoelectric oscillator of this embodiment, when an arbitrary bias voltage is applied to the gate terminal of the PMOS transistor 15, which constitutes the amplifier 41, the gate-source voltage VGS of the PMOS transistor 15 can be raised and a large gain for the amplifier 41 can be obtained. Therefore, a satisfactory negative resistance is ensured, even during low-voltage operation. In addition, when the internal regulator voltage is three times or higher than the threshold voltage of an MOS transistor, the negative resistance can still be increased in a high frequency band.

Further, the phases of oscillated signals at the gate terminal of the PMOS transistor 15 and at the gate terminal of the NMOS transistor 17 are the same, and when the NMOS transistor 17 is ON, the PMOS transistor 15 is OFF. Thus, power consumption can be reduced, compared with when, as in prior art 2 in FIG. 11, a constant current is supplied to the NMOS transistor 10.

### Second Embodiment

FIG. 2 is a schematic diagram showing the arrangement of a piezoelectric oscillator according to a second embodiment of the present invention. The piezoelectric oscillator of the second embodiment comprises an oscillator circuit that includes: a piezoelectric vibrator 19, such as a crystal vibrator; an NMOS transistor 17 and a first PMOS transistor 15, which constitute an amplifier 41 connected in parallel to the piezoelectric vibrator 19; and load capacitors 20 and 21, which are connected in parallel to the piezoelectric vibrator 19. A gate terminal 32 of the NMOS transistor 17 and a gate terminal 30 of the first PMOS transistor 15, which together constitute the amplifier 41, are connected by a DC cut capacitor 22, and the gate terminal 32 of the NMOS transistor 17 and an output terminal 31 of the amplifier 41 are connected by a feedback resistor 16. Further, an arbitrary bias voltage is applied to the gate terminal 30 of the first PMOS transistor 15 via a high-frequency elimination resistor 23. A circuit (a bias voltage generator circuit) that is comprised of a second PMOS transistor 25 that is diode-connected, and a current source 26 generates this bias voltage. Here, as same as the first embodiment, the arbitrary bias voltage that is smaller than half of the power voltage VDD of the amplifier 41 needs to be applied to the gate terminal of the first PMOS transistor 15.

As shown in FIG. 2, according to the piezoelectric oscillator of the second embodiment, the current source 26 and the diode-connected PMOS transistor 25, the gate terminal and the drain terminal of which are short-circuited, are arranged between the internal regulator power voltage VDD and the GND, and this circuit is used to generate the bias voltage. By changing the strength of the current that flows through the current source 26, an optimal current for the oscillator can be designated, a current value of the current source can be set so that the bias voltage becomes smaller than half of the source voltage of the amplifier 41. Here, a load resistor may be employed instead of the current source 26.

With this arrangement, a bias voltage is applied to the gate terminal 30 of the first PMOS transistor 15 in order to offset a threshold voltage VT and the thermal characteristics of the first PMOS transistor 15. Here, in order to offset the threshold voltage VT and the thermal characteristics of the PMOS transistor 15, it is necessary to set a condition in which a power voltage VDD of the first PMOS transistor 15 is equal to a power voltage VDD of the second PMOS transistor 25, a gate-source voltage of the first PMOS transistor 15 is equal to a gate-source voltage of the second PMOS transistor 25, a gate width of the first PMOS transistor 15 is larger than a gate width of the second PMOS transistor 25, and a gate length of the first PMOS transistor 15 is smaller than a gate width of the second PMOS transistor 25.

As described above, according to the piezoelectric oscillator of this embodiment, since a bias voltage is applied to the gate terminal of the PMOS transistor 15 to offset a variation in the threshold voltage VT and the thermal characteristics of the PMOS transistor 15, power consumption, a variation in the negative resistance and a change due to the thermal characteristics can be reduced. Furthermore, since noise produced by the power source of the amplifier 41 can be offset, phase noise can also be lowered.

### Third Embodiment

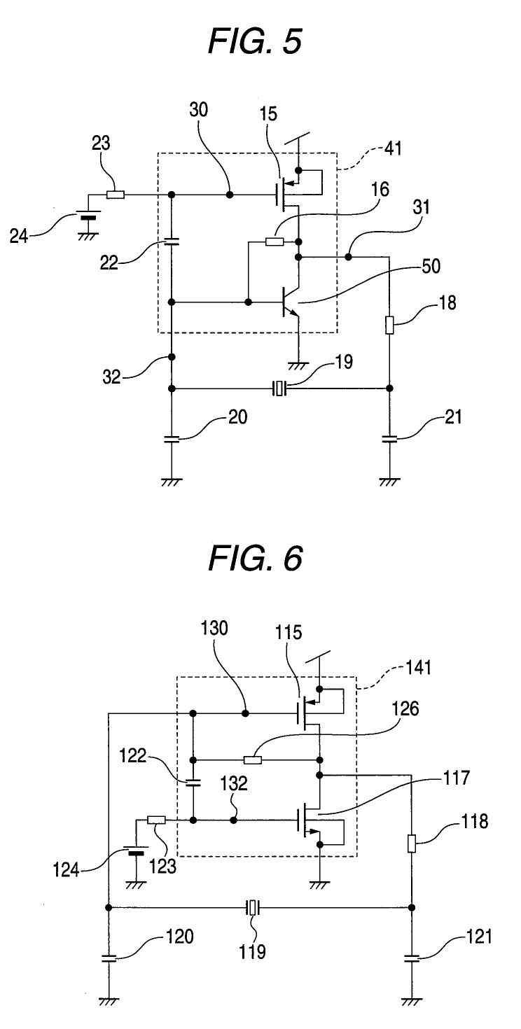

FIG. 5 is a schematic diagram showing the arrangement of a piezoelectric oscillator according to a third embodiment of the present invention. According to the piezoelectric oscillator of the third embodiment, an NPN transistor 50 is used to replace the NMOS transistor 17 of the piezoelectric oscillator in FIG. 1, for the first embodiment. It should further be noted that the NPN transistor 50 may also be used to replace the NMOS transistor 17 of the piezoelectric oscillator in FIG. 2, for the second embodiment.

In the first and second embodiments, the negative resistance depends on the gain for the NMOS transistor 17, and when as shown in FIG. 5 the NPN transistor 50 is employed instead of the NMOS transistor 17, more improvement for the negative resistance can be obtained.

As described above, according to the piezoelectric oscillator of this embodiment, when an arbitrary bias voltage is applied to the gate of a PMOS transistor 15 of an amplifier 41, the gate-source voltage VGS of the PMOS transistor 15 can be increased, and for the amplifier 41, a large gain can be obtained. Furthermore, even during a low-voltage operation, a greater improvement in negative resistance is possible.

### Fourth Embodiment

Although an arbitrary bias voltage is to be applied to the gate terminal of the PMOS transistor in the first embodiment, as shown in the fourth embodiment, it is possible to configure so that an arbitrary bias voltage can be applied to the gate terminal of the NMOS transistor.

FIG. 6 is a schematic diagram showing the arrangement of a piezoelectric oscillator according to this fourth embodiment of the present invention. The piezoelectric oscillator of the fourth embodiment of the invention comprises an oscillator circuit that includes: a piezoelectric vibrator 119, such as a crystal vibrator; a PMOS transistor 115 and an NMOS transistor 117 that constitute an amplifier 141 connected in parallel to the piezoelectric vibrator 119; and load capacitors 120 and 121 that are connected in parallel to the piezoelectric vibrator 119. A gate terminal 130 of the PMOS transistor 115 and a gate terminal 132 of the NMOS transistor 117, both of which are constituents of the amplifier 141, are connected by a DC cut capacitor 122, and the gate terminal 130 of the PMOS transistor 115 and an output terminal 131 of the amplifier 141 are connected by a feedback resistor 116. Further, an arbitrary bias voltage 124 is to be applied to the gate terminal 132 of the NMOS transistor 117 via a high-frequency elimination resistor 123.

Here, although the arbitrary bias voltage that is smaller than half of the power voltage VDD of the CMOS inverter amplifier needs to be applied in the first embodiment, in the forth embodiment, the arbitrary bias voltage 124 that is larger than half of the power voltage VDD of the amplifier 141 need to be applied.

As described above, according to the piezoelectric oscillator of this fourth embodiment, even when an arbitrary bias voltage is applied to the gate terminal of the NMOS transistor 117, which constitutes the amplifier 141, a satisfactory negative resistance is also ensured, even during low-voltage operation.

### Fifth Embodiment

Also, although an arbitrary bias voltage is to be applied to the gate terminal of the PMOS transistor in the second embodiment, as shown in the fifth embodiment, it is possible to configure so that an arbitrary bias voltage can be applied to the gate terminal of the NMOS transistor.

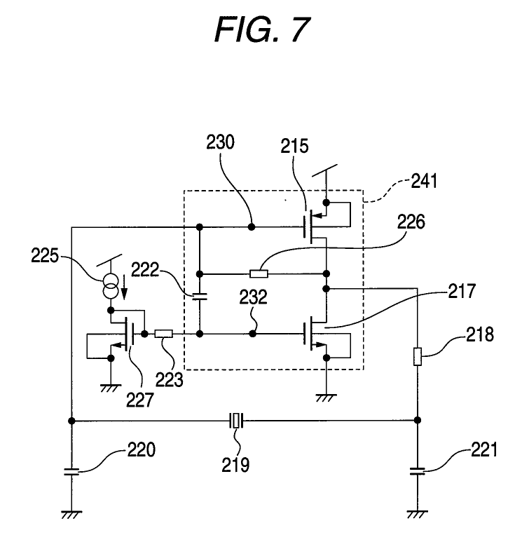

FIG. 7 is a schematic diagram showing the arrangement of a piezoelectric oscillator according to a fifth embodiment of the present invention. The piezoelectric oscillator of the fifth embodiment comprises an oscillator circuit that includes: a piezoelectric vibrator 219, such as a crystal vibrator; a PMOS transistor 215 and an first NMOS transistor 217, which constitute an amplifier 241 connected in parallel to the piezoelectric vibrator 219; and load capacitors 220 and 221, which are connected in parallel to the piezoelectric vibrator 219. A gate terminal 232 of the first NMOS transistor 217 and a gate terminal 230 of the PMOS transistor 215, which together constitute the amplifier 241, are connected by a DC cut capacitor 222, and the gate terminal 230 of the PMOS transistor 215 and an output terminal 231 of the amplifier 241 are connected by a feedback resistor 216. Further, an arbitrary bias voltage is applied to the gate terminal 230 of the first NMOS transistor 217 via a high-frequency elimination resistor 223. A circuit (a bias voltage generator circuit) that is comprised of a second NMOS transistor 227 that is diode-connected, and a current source 226 generates this bias voltage.

Here, although the arbitrary bias voltage that is smaller than half of the power voltage VDD of the CMOS inverter amplifier needs to be applied in the second embodiment, in the fifth embodiment, the arbitrary bias voltage that is larger than half of the power voltage VDD of the amplifier 241 need to be applied.

As shown in FIG. 7, according to the piezoelectric oscillator of the fifth embodiment, the current source 226 and the diode-connected NMOS transistor 227, the gate terminal and the drain terminal of which are short-circuited, are arranged between the internal regulator power voltage VDD and the GND, and this circuit is used to generate the bias voltage. By changing the strength of the current that flows through the current source 226, an optimal current for the oscillator can be designated, a current value of the current source can be set so that the bias voltage becomes smaller than half of the source voltage of the amplifier 241. Here, a load resistor may be employed instead of the current source 226.

With this arrangement, a bias voltage is applied to the gate terminal 232 of the first NMOS transistor 217 in order to offset a threshold voltage VT and the thermal characteristics of the first NMOS transistor 217. Here, in order to offset the threshold voltage VT and the thermal characteristics of the first NMOS transistor 217, it is necessary to set a condition in which a power voltage VDD of the first NMOS transistor 217 is equal to a power voltage VDD of the second PMOS transistor 227, a gate-source voltage of the first NMOS transistor 217 is equal to a gate-source voltage of the second PMOS transistor 227, a gate width of the first NMOS transistor 217 is larger than a gate width of the second PMOS transistor 227, and a gate length of the first NMOS transistor 217 is smaller than a gate width of the second NMOS transistor 227.

As described above, according to the piezoelectric oscillator of this embodiment, since a bias voltage is applied to the gate terminal of the NMOS transistor 217 to offset a variation in the threshold voltage VT and the thermal characteristics of the first NMOS transistor 217, power consumption, a variation in the negative resistance and a change due to the thermal characteristics can be reduced. Furthermore, since noise produced by the power source of the amplifier 241 can be offset, phase noise can also be lowered.

### Sixth Embodiment

Also, although the NPN transistor 50 is replaced with the NMOS transistor 17 of the piezoelectric oscillator in the third embodiment, as shown in the sixth embodiment, it is possible to configure so that an PNP transistor 70 is used to replace the PMOS transistor 15 of the piezoelectric oscillator in FIG. 1, for the first embodiment.

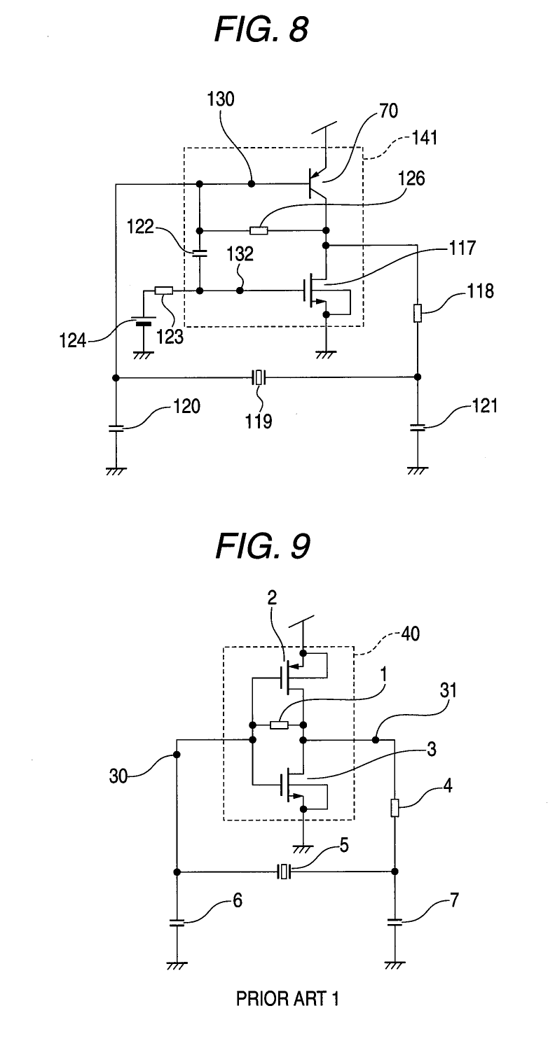

As shown in FIG. 8, it should further be noted that the PNP transistor 70 can also be used to replace the PMOS transistor 115 of the piezoelectric oscillator in FIG. 6, for the fourth embodiment.

The effects provided by the present invention are that a satisfactory negative resistance can continue to be obtained when the invention is employed during a low-voltage operation, and that the temperature-compensated crystal oscillator of the invention can be used for the low-voltage operation of a cellular phone or a GPS.

What is claimed is:

1. A piezoelectric oscillator, comprising:
an amplifier connected in parallel to a piezoelectric vibrator; and
an load capacitor connected in parallel to the piezoelectric vibrator,
wherein the amplifier includes:
an inverter comprised of a first PMOS transistor and an NMOS transistor that are connected in series;
a DC cut capacitor connected between a gate terminal of the first PMOS transistor and a gate terminal of the NMOS transistor; and
a feedback resistor connected between the gate terminal of the NMOS transistor and an output terminal of the amplifier; and
wherein a bias voltage that is smaller than half of a source voltage of the inverter is to be applied to the gate terminal of the first PMOS transistor.

2. The piezoelectric oscillator according to claim 1, further comprising:
a high-frequency elimination resistor connected to the gate terminal of the first PMOS transistor,
wherein the bias voltage is to be applied via the high-frequency elimination resistor.

3. The piezoelectric oscillator according to claim 1, further comprising:
a bias voltage generator circuit generating the bias voltage,
wherein the bias voltage generator circuit includes:
a second PMOS transistor that is diode-connected, and
a current source connected in series to the second PMOS transistor.

4. The piezoelectric oscillator according to claim 3, wherein:
the source voltage of the first PMOS transistor is equal to a source voltage of the second PMOS transistor;
a gate-source voltage of the first PMOS transistor is equal to a gate-source voltage of the second PMOS transistor:
a gate width of the first PMOS transistor is larger than a gate width of the second PMOS transistor; and
a gate length of the first PMOS transistor is smaller than a gate width of the second PMOS transistor.

5. The piezoelectric oscillator according to claim 4, wherein a current value of the current source is set so that the bias voltage becomes smaller than half of the source voltage of the inverter.

6. The piezoelectric oscillator according to claim 1, further comprising:
a bias voltage generator circuit for generating the bias voltage,
wherein the bias voltage generator circuit includes
a second PMOS transistor that is diode-connected, and
a load resistor connected in series to the second PMOS transistor.

7. A piezoelectric oscillator comprising:
an amplifier connected in parallel to a piezoelectric vibrator; and
a load capacitor connected in parallel to the piezoelectric vibrator,
wherein the amplifier includes:
an inverter that is comprised of a PMOS transistor and an NPN transistor connected in series,
a DC cut capacitor connected between a gate terminal of the PMOS transistor and a base terminal of the NPN transistor, and
a feedback resistor connected between the base terminal of the NPN transistor and an output terminal of the amplifier, and
wherein a bias voltage that is smaller than half of a source voltage of the inverter is to be applied to the gate terminal of the PMOS transistor.

8. A piezoelectric oscillator, comprising:
an amplifier connected in parallel to a piezoelectric vibrator; and
an load capacitor connected in parallel to the piezoelectric vibrator,
wherein the amplifier includes:
an inverter that is comprised of a first NMOS transistor and an PMOS transistor that are connected in series,
a DC cut capacitor connected between a gate terminal of the first NMOS transistor and a gate terminal of the PMOS transistor and
a feedback resistor connected between the gate terminal of the PMOS transistor and an output terminal of the amplifier, and
wherein a bias voltage that is larger than half of a source voltage of the inverter is to be applied to the gate terminal of the first NMOS transistor.

9. The piezoelectric oscillator according to claim 8, further comprising:
a high-frequency elimination resistor connected to the gate terminal of the first NMOS transistor,
wherein the bias voltage is to be applied via the high-frequency elimination resistor.

10. The piezoelectric oscillator according to claim 8, further comprising:
a bias voltage generator circuit generating the bias voltage,
wherein the bias voltage generator circuit includes:
a second NMOS transistor that is diode-connected, and
a current source connected in series to the second NMOS transistor.

11. The piezoelectric oscillator according to claim 8, further comprising:
a bias voltage generator circuit generating the bias voltage,
wherein the bias voltage generator circuit includes:
a second NMOS transistor that is diode-connected, and
a load resistor connected in series to the second NMOS transistor.

12. A piezoelectric oscillator, comprising:
an amplifier connected in parallel to a piezoelectric vibrator; and
an load capacitor connected in parallel to the piezoelectric vibrator,
wherein the amplifier includes:
an inverter that is comprised of a NMOS transistor and an PNP transistor that are connected in series,
a DC cut capacitor connected between a gate terminal of the NMOS transistor and a base terminal of the PNP transistor and
a feedback resistor connected between the base terminal of the PNP transistor and an output terminal of the amplifier, and
wherein a predetermined bias voltage is to be applied to the gate terminal of the NMOS transistor.
